(19) United States
(12) Patent Application Publication
(10) Pub. No.: US 2024/0256752 A1
(43) Pub. Date: Aug. 1, 2024

(54) METHOD FOR DESIGNING SEMICONDUCTOR BASED ON GROUPING MACRO CELLS

(71) Applicant: MakinaRocks Co., Ltd., Seoul (KR)

(72) Inventors: Wooshik MYUNG, Seoul (KR); Jiyoon LIM, Seoul (KR); Seungju KIM, Seoul (KR); Wonjun YOO, Seoul (KR)

(21) Appl. No.: 18/421,870

(22) Filed: Jan. 24, 2024

(30) Foreign Application Priority Data
Jan. 26, 2023 (KR) 10-2023-0010012

(51) Int. Cl. G06F 30/392

(52) U.S. Cl. CPC G06F 30/392

(57) ABSTRACT

Disclosed is a method for designing a semiconductor, which is performed by a computing device. The method may include acquiring connection relationship information between cells to be placed. The method may include generating two or more macro groups by grouping macro cells included in the connection relationship information. The method may include placing the two or more macro groups in a design area, and the two or more macro groups may be generated based on layer information included in the connection relationship information.

### CROSS-REFERENCE TO RELATED APPLICATIONS

This application claims priority to and the benefit of Korean Patent Application No. 10-2023-0010012 filed in the Korean Intellectual Property Office on Jan. 26, 2023, the entire contents of which are incorporated herein by reference.

### BACKGROUND

### Technical Field

The present disclosure relates to a semiconductor designing method, and more particularly, to a method for simplifying design by grouping macro cells into several chunks during a semiconductor design process.

This study was conducted as part of the private intelligent information service expansion project by the Ministry of Science and ICT and the National IT Industry Promotion Agency (A0903-21-1021, Development of an AI-based semiconductor design automation system).

### Description of the Related Art

Since a current semiconductor design process relies on engineer's experience and intuition, there may be significant differences in design quality depending on the engineer's skill level. However, due to this aspect, it is difficult to maintain consistent design quality of semiconductors, and significant time and financial costs must be invested for design. Therefore, recently, there have been increasing attempts to automate part of this design process using artificial intelligence models.

Korean Patent Unexamined Publication No. 10-0296183 (Oct. 22, 2001) discloses Method for Designing Semiconductor Integrated Circuit.

### BRIEF SUMMARY

As the number of cases that the artificial intelligence model must consider in the process of automation increases, the difficulty of the problem increases, making it difficult for the artificial intelligence model to derive the optimal design. Therefore, the inventors of the present disclosure have appreciated that when designing semiconductors using artificial intelligence models, a solution is needed to simplify complex semiconductor design problems.

Various embodiments of the present disclosure have been derived at least based on one or more technical problems in the related art including the problem identified above. The present disclosure has been made in an effort to automate a logical design process of semiconductors that relies on human intuition using artificial intelligence and improve the accuracy and efficiency of semiconductor design based on grouping macro cells.

Meanwhile, the technical benefits to be achieved by the present disclosure is not limited to the above-mentioned technical benefits, and various technical objects can be included within the scope which is apparent to those skilled in the art from contents to be described below.

An exemplary embodiment of the present disclosure provides a method for designing a semiconductor, which is performed by a computing device. The method may include: acquiring connection relationship information between cells to be placed; generating two or more macro groups by grouping macro cells included in the connection relationship information; and placing the two or more macro groups in a design area, and the two or more macro groups may be generated based on layer information included in the connection relationship information.

As an exemplary embodiment, the placing of the two or more macro groups in the design area may include determining a formation of each macro group, and determining a placement position of each macro group.

As an exemplary embodiment, the determining of the placement position of each macro group may include determining a reference position in each macro group, determining the placement position of each macro group in the design area, and placing each macro group to match the placement position and the reference position each other.

As an exemplary embodiment, the reference position of the macro group may include a center point of a bounding box of a selected macro group, a center-bottom point of the bounding box of the selected macro group, a center-top point of the bounding box of the selected macro group, a center-leftmost point of the bounding box of the selected macro group, or a center-rightmost point of the bounding box of the selected macro group.

As an exemplary embodiment, the design area may include a canvas, the canvas may include a grid-shaped space, and the placement position may correspond to one area in the grid-shaped space.

As an exemplary embodiment, the canvas in which the two or more macro groups are placed for design may include a grid-shaped discrete space, and a die in which the two or more macro groups are to be placed may include a continuous space.

As an exemplary embodiment, each macro group may include a margin area formed between at least two macro cells.

As an exemplary embodiment, the connection relationship information includes a netlist, and each macro group includes macro cells belonging to a same layer in the netlist.

As an exemplary embodiment, each macro group may include macro cells belonging to the same layer, and having a same cell type or a same size in the netlist.

As an exemplary embodiment, the determining of the formation of each macro group may include selecting at least one of a plurality of matrix forms with respect to each macro group, and determining a form of the macro cells included in each macro group are to maintain together based on a selected matrix form with respect to each macro group.

As an exemplary embodiment, the selecting of at least one of the plurality of matrix forms with respect to each macro group may include selecting two or more matrix forms, and the determining of the form which the macro cells included in each macro group are to maintain together based on a selected matrix form with respect to each macro group may include determining the form which the macro cells included in each macro group are to maintain together based on a form in which the two or more matrix forms are combined.

As an exemplary embodiment, the placing of the two or more macro groups in the design area may include performing reinforcement learning based on a reward related to macro group-unit placement.

As an exemplary embodiment, an action of the reinforcement learning may include determining formations of macro cells included in a macro group to be placed, and determining a placement position of the macro group to be placed.

As an exemplary embodiment, the reward related to the macro group-unit placement may be calculated based on at least one of a connection or a congestion between cells computed by considering both the formation and the placement position of the macro group to be placed.

As an exemplary embodiment, the reward related the macro group-unit placement may be calculated based on at least one of a connection between cells to be included in the design area, a congestion between the cells to be included in the design area, an integration of the cells to be included in the design area, or energy consumption due to the wires and cells to be included in the design area.

Another exemplary embodiment of the present disclosure provides a computing device. The device as a computing device for designing a semiconductor may include: at least one processor; and a memory, and at least one processor may be configured to acquire connection relationship information between cells to be placed, generate two or more macro groups by grouping macro cells included in the connection relationship information, and place the two or more macro groups in a design area, and the two or more macro groups may be generated based on layer information included in the connection relationship information.

As an exemplary embodiment related to the device, the at least one processor may be additionally configured to place the two or more macro groups in a design area, determine a formation of each macro group, and determine a placement position of each macro group.

As an exemplary embodiment related to the device, the at least one processor may be additionally configured to determine a reference position in each macro group, determine the placement position of each macro group in the design area, and place each macro group to match the placement position and the reference position each other.

As an exemplary embodiment related to the device, the reference position of the macro group may include a center point of a bounding box of a selected macro group, a center-bottom point of the bounding box of the selected macro group, a center-top point of the bounding box of the selected macro group, a center-leftmost point of the bounding box of the selected macro group, or a center-rightmost point of the bounding box of the selected macro group.

As an exemplary embodiment related to the device, the connection relationship information includes a netlist, and each macro group includes macro cells belonging to a same layer in the netlist.

As an exemplary embodiment related to the device, each macro group may include macro cells belonging to the same layer, and having a same cell type or a same size in the netlist.

As an exemplary embodiment related to the device, the at least one processor may be additionally configured to determine the formation of each macro group, select at least one of a plurality of matrix forms with respect to each macro group, and determine a form which the macro cells included in each macro group are to maintain together based on a selected matrix form with respect to each macro group.

As an exemplary embodiment related to the device, the at least one processor may be additionally configured to select two or more matrix forms in relation to selecting at least one of the plurality of matrix forms, and determine the form which the macro cells included in each macro group are to maintain together based on a form in which the two or more matrix forms are combined in relation to determining the form which the macro cells are to maintain together.

Still another exemplary embodiment of the present disclosure provides a program. The program as a computer program stored in a computer-readable storage medium, and when the computer program is executed by at least one processor, the computer program allows the one or more processors to perform operations of designing a semiconductor, and the operations may include: an operation of acquiring connection relationship information between cells to be placed; an operation of generating two or more macro groups by grouping macro cells included in the connection relationship information; and an operation of placing the two or more macro groups in a design area, and the two or more macro groups may be generated based on layer information included in the connection relationship information.

As an exemplary embodiment related to the program, the operation of placing of the two or more macro groups in the design area may include an operation of performing reinforcement learning based on a reward related to macro group-unit placement.

As an exemplary embodiment related to the program, an action of the reinforcement learning may include determining formations of macro cells included in a macro group to be placed, and determining a placement position of the macro group to be placed.

As an exemplary embodiment related to the program, the reward related to the macro group-unit placement may be calculated based on at least one of a connection or a congestion between cells computed by considering both the formation and the placement position of the macro group to be placed.

As an exemplary embodiment related to the program, the reward related the macro group-unit placement may be calculated based on at least one of a connection between cells to be included in the design area, a congestion between the cells to be included in the design area, an integration of the cells to be included in the design area, or energy consumption due to the wires and cells to be included in the design area.

According to an exemplary embodiment of the present disclosure, a design problem is simplified by grouping macro cells when designing a semiconductor using an artificial intelligence model, thereby reducing the time and cost required for the design process.

In addition, according to the present disclosure, a solution that can optimally place macro groups created by grouping macro cells can be provided. For example, according to the present disclosure, so that connectivity between elements can be simplified and congestion can be reduced by performing reinforcement learning based on rewards calculated by considering both the formation and placement position of each macro group, macro cells can be placed.

In addition, according to the present disclosure, design errors that may occur in relation to the placement of macro cells can be reduced. For example, according to the present disclosure, the number of placements performed in the design process can be reduced by performing placement in units of macro groups rather than in units of individual macro cells, thereby reducing the number of occurrences of design errors. In addition, according to the present disclosure, “an error which occurs due to an environmental difference in which the design is performed in a grid shape discrete space, and elements are placed in continuous spaces” is allowed to occur in a macro group unit, and is prevented from occurring in individual macro units, thereby further reducing design errors. In addition, according to the present disclosure, since a margin area that can reduce errors internally in each macro group can be set, the design errors can be further reduced.

Meanwhile, the effects of the present disclosure are not limited to the above-mentioned effects, and various effects can be included within the scope which is apparent to those skilled in the art from contents to be described below.

### BRIEF DESCRIPTION OF THE SEVERAL VIEWS OF THE DRAWINGS

FIG. 1 is a block diagram of a computing device according to an exemplary embodiment of the present disclosure.

FIG. 2 is a conceptual view illustrating a neural network according to an exemplary embodiment of the present disclosure.

FIG. 3 is a schematic view illustrating a basic semiconductor design process.

FIG. 4 is a conceptual view illustrating a reinforcement learning process.

FIG. 5 is an exemplary diagram of a semiconductor designed by using grouping.

FIG. 6 is an exemplary diagram illustrating a method for grouping macro cells according to an exemplary embodiment of the present disclosure.

FIGS. 7A, 7B, and 7C are exemplary diagrams for a form of a macro group according to an exemplary embodiment of the present disclosure.

FIG. 8 is an exemplary diagram for a method for placing a macro group according to an exemplary embodiment of the present disclosure.

FIG. 9 is a flowchart illustrating a schematic sequence for a method for designing a semiconductor according to an exemplary embodiment of the present disclosure.

FIG. 10 is a conceptual view of a computing environment according to an exemplary embodiment of the present disclosure.

### DETAILED DESCRIPTION

Various exemplary embodiments are described with reference to the drawings. In the present specification, various descriptions are presented for understanding the present disclosure. However, it is obvious that the exemplary embodiments may be carried out even without a particular description.

Terms, “component,” “module,” “system,” and the like used in the present specification indicate a computer-related entity, hardware, firmware, software, a combination of software and hardware, or execution of software. For example, a component may be a procedure executed in a processor, a processor, an object, an execution thread, a program, and/or a computer, but is not limited thereto. For example, both an application executed in a computing device and a computing device may be components. One or more components may reside within a processor and/or an execution thread. One component may be localized within one computer. One component may be distributed between two or more computers. Further, the components may be executed by various computer readable media having various data structures stored therein. For example, components may communicate through local and/or remote processing according to a signal (for example, data transmitted to another system through a network, such as the Internet, through data and/or a signal from one component interacting with another component in a local system and a distributed system) having one or more data packets.

Further, a term “or” intends to mean comprehensive “or” not exclusive “or.” That is, unless otherwise specified or when it is unclear in context, “X uses A or B” intends to mean one of the natural comprehensive substitutions. That is, in the case where X uses A; X uses B; or, X uses both A and B, “X uses A or B” may apply to either of these cases. Further, a term “and/or” used in the present specification shall be understood to designate and include all of the possible combinations of one or more items among the listed relevant items.

Further, a term “include” and/or “including” shall be understood as meaning that a corresponding characteristic and/or a constituent element exists. Further, it shall be understood that a term “include” and/or “including” means that the existence or an addition of one or more other characteristics, constituent elements, and/or a group thereof is not excluded. Further, unless otherwise specified or when it is unclear that a single form is indicated in context, the singular shall be construed to generally mean “one or more” in the present specification and the claims.

Further, the term “at least one of A and B” should be interpreted to mean “the case including only A,” “the case including only B,” and “the case where A and B are combined.”

Those skilled in the art shall recognize that the various illustrative logical blocks, configurations, modules, circuits, means, logic, and algorithm operations described in relation to the exemplary embodiments additionally disclosed herein may be implemented by electronic hardware, computer software, or in a combination of electronic hardware and computer software. In order to clearly exemplify interchangeability of hardware and software, the various illustrative components, blocks, configurations, means, logic, modules, circuits, and operations have been generally described above in the functional aspects thereof. Whether the functionality is implemented as hardware or software depends on a specific application or design restraints given to the general system. Those skilled in the art may implement the functionality described by various methods for each of the specific applications. However, it shall not be construed that the determinations of the implementation deviate from the range of the contents of the present disclosure.

The description about the presented exemplary embodiments is provided so as for those skilled in the art to use or carry out the present disclosure. Various modifications of the exemplary embodiments will be apparent to those skilled in the art. General principles defined herein may be applied to other exemplary embodiments without departing from the scope of the present disclosure. Therefore, the present disclosure is not limited to the exemplary embodiments presented herein. The present disclosure shall be interpreted within the broadest meaning range consistent to the principles and new characteristics presented herein.

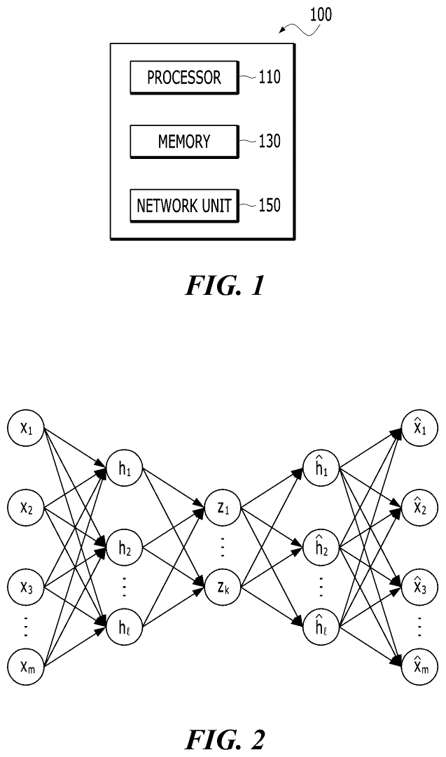

FIG. 1 is a block diagram of a computing device for automating semiconductor design based on artificial intelligence according to an exemplary embodiment of the present disclosure.

The computing device 100 may include a processor 110, a memory 130, and a network unit 150.

The processor 110 may be constituted by one or more cores, and include processors for data analysis and deep learning, such as a central processing unit (CPU), a general purpose graphics processing unit (GPGPU), a tensor processing unit (TPU), etc., of the computing device. The processor 110 may read a computer program stored in the memory 130 and process data for machine learning according to an exemplary embodiment of the present disclosure. According to an exemplary embodiment of the present disclosure, the processor 110 may perform an operation for learning the neural network. The processor 110 may perform calculations for learning the neural network, which include processing of input data for learning in deep learning (DL), extracting a feature in the input data, calculating an error, updating a weight of the neural network using backpropagation, and the like. At least one of the CPU, the GPGPU, and the TPU of the processor 110 may process learning of the network function. For example, the CPU and the GPGPU may process the learning of the network function and data classification using the network function jointly. In addition, in an exemplary embodiment of the present disclosure, the learning of the network function and the data classification using the network function may be processed by using processors of a plurality of computing devices together. In addition, the computer program performed by the computing device according to an exemplary embodiment of the present disclosure may be a CPU, GPGPU, or TPU executable program.

According to an exemplary embodiment of the present disclosure, the processor 110 may generate two or more macro groups by grouping macro cells based on connection relationship information of semiconductor cells. For example, before placing semiconductor cells, the processor 110 may use the connection relationship information to group the macro cells of the semiconductor, and use the groped macro cells for placement. As an exemplary embodiment, the processor 110 places grouped macro cells (hereinafter referred to as macro groups), rather than in units of individual macro cells, in a design area (e.g., canvas) by using a reinforcement learning model to significantly reduce a computation amount to be considered by the reinforcement learning model, thereby facilitating learning and prediction, as compared with placing the macro cells in units of individual macro cells. That is, the reinforcement learning model according to an exemplary embodiment of the present disclosure may perform a computation primarily between the macro groups, and perform a computation in units of the individual macro cells internally in the respective groups to simplify configurations of episodes of reinforcement learning and reduce the computation amount in the process of calculating the reward of the reinforcement learning.

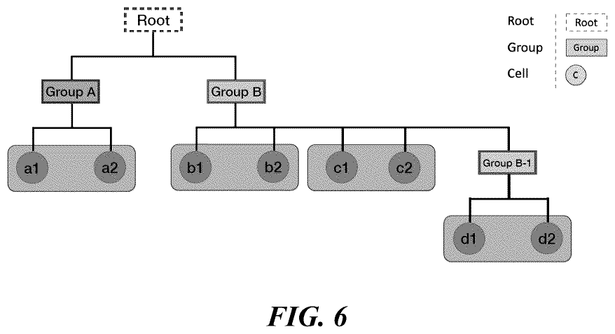

According to an exemplary embodiment of the present disclosure, the connection relationship information may include Netlist information indicating a connection relationship between semiconductor cells. Here, the Netlist may include information on a net indicating connectivity of the semiconductor cells. Further, the connection relationship information including the Netlist may be expressed in the form of a graph including a kind of layer as in FIG. 6, and information on the layer will be hereinafter referred to as layer information.

In an exemplary embodiment, the processor 110 may acquire the layer information which is the information on the layer based on the connection relationship information. In this case, in relation to generating the macro group mentioned above, the processor 110 may group macro cells based on the layer information included in the connection relationship information. For example, the processor 110 may group macro cells included in the same layer based on the layer information acquired in the Netlist. As an additional exemplary embodiment, the processor 110 may group the macro cells included in the same layer based on the layer information, and groups the macro cells by additionally considering sizes (e.g., horizontal and vertical sizes) or names (e.g., names expressing element types) of the macro cells. For example, the processor 110 may determine a1 and a2 which are macro cells included in a first layer as macro group-A, and determine b1, b2, c1, c2, d1, and d2 which are macro cells included in a second layer as a second macro group. In this case, the processor 110 may also generate a third macro group by separately separating d1 and d2 having different types from other macros in the second macro group.

According to an exemplary embodiment of the present disclosure, the memory 130 may store any type of information generated or determined by the processor 110 or any type of information received by the network unit 150.

According to an exemplary embodiment of the present disclosure, the memory 130 may include at least one type of storage medium of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The computing device 100 may operate in connection with a web storage performing a storing function of the memory 130 on the Internet. The description of the memory is just an example and the present disclosure is not limited thereto.

The network unit 150 according to an exemplary embodiment of the present disclosure may use an arbitrary type of known wired/wireless communication system.

The network unit 150 may receive information for the semiconductor design from an external system. For example, the network unit 150 may receive semiconductor related information including connection relationship information from a database. In this case, the information received from the database may be data for learning or data for inference of the neural network model (for example, a reinforcement learning model).

In addition, the network unit 150 may transmit and receive information processed by the processor 110, a user interface, and the like through communication with other terminals. For example, the network unit 150 may provide the user interface generated by the processor 110 to a client (e.g., a user terminal). In addition, the network unit 150 may receive an external input of a user applied to a client and transfer the external input to the processor 110. In this case, the processor 110 may process operations such as outputting, correcting, changing, adding, and the like of information provided through the user interface based on the external input of the user received from the network unit 150.

Meanwhile, according to an exemplary embodiment of the present disclosure, the computing device 100 may include a server as a computing system that transmits and receives information through communication with the client. In this case, the client may be any type of terminal which may access the server. For example, the computing device 100 as the server may receive information for the semiconductor design from the external database, and generate a design result, and provide a user interface for a logical design result to the user terminal. At this time, the user terminal may output the user interface received from the computing device 100 as the server, and receive or process information through interaction with the user. For example, the computing device 100 may also include any type of terminal that receives data resources generated by an arbitrary server and performs additional information processing.

FIG. 2 is a schematic diagram illustrating a neural network according to the embodiment of the present disclosure.

A neural network model according to the embodiment of the present disclosure may include a neural network for logical design of semiconductors. The neural network may be formed of a set of interconnected calculation units which are generally referred to as “nodes.” The “nodes” may also be called “neurons.” The neural network consists of one or more nodes. The nodes (or neurons) configuring the neural network may be interconnected by one or more links.

In the neural network, one or more nodes connected through the links may relatively form a relationship of an input node and an output node. The concept of the input node is relative to the concept of the output node, and a predetermined node having an output node relationship with respect to one node may have an input node relationship in a relationship with another node, and a reverse relationship is also available. As described above, the relationship between the input node and the output node may be generated based on the link. One or more output nodes may be connected to one input node through a link, and a reverse case may also be valid.

In the relationship between an input node and an output node connected through one link, a value of the output node data may be determined based on data input to the input node. Herein, a link connecting the input node and the output node may have a weight. The weight is variable, and in order for the neural network to perform a desired function, the weight may be varied by a user or an algorithm. For example, when one or more input nodes are connected to one output node by links, respectively, a value of the output node may be determined based on values input to the input nodes connected to the output node and weights set in the link corresponding to each of the input nodes.

As described above, in the neural network, one or more nodes are connected with each other through one or more links to form a relationship of an input node and an output node in the neural network. A characteristic of the neural network may be determined according to the number of nodes and links in the neural network, a correlation between the nodes and the links, and a value of the weight assigned to each of the links. For example, when there are two neural networks in which the numbers of nodes and links are the same and the weight values between the links are different, the two neural networks may be recognized to be different from each other.

The neural network may consist of a set of one or more nodes. A subset of the nodes configuring the neural network may form a layer. Some of the nodes configuring the neural network may form one layer on the basis of distances from an initial input node. For example, a set of nodes having a distance of n from an initial input node may form n layers. The distance from the initial input node may be defined by the minimum number of links, which need to be passed to reach a corresponding node from the initial input node. However, the definition of the layer is arbitrary for the description, and a degree of the layer in the neural network may be defined by a different method from the foregoing method. For example, the layers of the nodes may be defined by a distance from a final output node.

The initial input node may mean one or more nodes to which data is directly input without passing through a link in a relationship with other nodes among the nodes in the neural network. Otherwise, the initial input node may mean nodes which do not have other input nodes connected through the links in a relationship between the nodes based on the link in the neural network. Similarly, the final output node may mean one or more nodes that do not have an output node in a relationship with other nodes among the nodes in the neural network. Further, the hidden node may mean nodes configuring the neural network, not the initial input node and the final output node.

In the neural network according to the embodiment of the present disclosure, the number of nodes of the input layer may be the same as the number of nodes of the output layer, and the neural network may be in the form that the number of nodes decreases and then increases again from the input layer to the hidden layer. Further, in the neural network according to another embodiment of the present disclosure, the number of nodes of the input layer may be smaller than the number of nodes of the output layer, and the neural network may be in the form that the number of nodes decreases from the input layer to the hidden layer. Further, in the neural network according to another embodiment of the present disclosure, the number of nodes of the input layer may be larger than the number of nodes of the output layer, and the neural network may be in the form that the number of nodes increases from the input layer to the hidden layer. The neural network according to another embodiment of the present disclosure may be the neural network in the form in which the foregoing neural networks are combined.

A deep neural network (DNN) may mean the neural network including a plurality of hidden layers, in addition to an input layer and an output layer. When the DNN is used, it is possible to recognize a latent structure of data. That is, it is possible to recognize latent structures of photos, texts, videos, voice, and music (for example, what objects are in the photos, what the content and emotions of the texts are, and what the content and emotions of the voice are). The DNN may include a convolutional neural network (CNN), a recurrent neural network (RNN), an auto encoder, Generative Adversarial Networks (GAN), a Long Short-Term Memory (LSTM), a transformer, a restricted Boltzmann machine (RBM), a deep belief network (DBN), a Q network, a U network, a Siamese network, a Generative Adversarial Network (GAN), and the like. The foregoing description of the deep neural network is merely illustrative, and the present disclosure is not limited thereto.

In the embodiment of the present disclosure, the network function may include an auto encoder. The auto encoder may be one type of artificial neural network for outputting output data similar to input data. The auto encoder may include at least one hidden layer, and the odd-numbered hidden layers may be disposed between the input/output layers. The number of nodes of each layer may decrease from the number of nodes of the input layer to an intermediate layer called a bottleneck layer (encoding), and then be expanded symmetrically with the decrease from the bottleneck layer to the output layer (symmetric with the input layer). The auto encoder may perform a nonlinear dimension reduction. The number of input layers and the number of output layers may correspond to the dimensions after preprocessing of the input data. In the auto encoder structure, the number of nodes of the hidden layer included in the encoder decreases as a distance from the input layer increases. When the number of nodes of the bottleneck layer (the layer having the smallest number of nodes located between the encoder and the decoder) is too small, the sufficient amount of information may not be transmitted, so that the number of nodes of the bottleneck layer may be maintained in a specific number or more (for example, a half or more of the number of nodes of the input layer and the like).

The neural network may be trained by at least one scheme of supervised learning, unsupervised learning, semi-supervised learning, and reinforcement learning. The training of the neural network may be a process of applying knowledge for the neural network to perform a specific operation to the neural network.

The neural network may be trained in a direction of minimizing an error of an output. In the training of the neural network, training data is repeatedly input to the neural network and an error of an output of the neural network for the training data and a target is calculated, and the error of the neural network is back-propagated in a direction from an output layer to an input layer of the neural network in order to decrease the error, and a weight of each node of the neural network is updated. In the case of the supervised learning, training data labelled with a correct answer (that is, labelled training data) is used, in each training data, and in the case of the unsupervised learning, a correct answer may not be labelled to each training data. That is, for example, the training data in the supervised learning for data classification may be data, in which category is labelled to each of the training data. The labelled training data is input to the neural network and the output (category) of the neural network is compared with the label of the training data to calculate an error. For another example, in the case of the unsupervised learning related to the data classification, training data that is the input is compared with an output of the neural network, so that an error may be calculated. The calculated error is back-propagated in a reverse direction (that is, the direction from the output layer to the input layer) in the neural network, and a connection weight of each of the nodes of the layers of the neural network may be updated according to the backpropagation. A change amount of the updated connection weight of each node may be determined according to a learning rate. The calculation of the neural network for the input data and the backpropagation of the error may configure a learning epoch. The learning rate is differently applicable according to the number of times of repetition of the learning epoch of the neural network. For example, at the initial stage of the learning of the neural network, a high learning rate is used to make the neural network rapidly secure performance of a predetermined level and improve efficiency, and at the latter stage of the learning, a low learning rate is used to improve accuracy.

In the training of the neural network, the training data may be generally a subset of actual data (that is, data to be processed by using the trained neural network), and thus an error for the training data is decreased, but there may exist a learning epoch, in which an error for the actual data is increased. Overfitting is a phenomenon, in which the neural network excessively learns training data, so that an error for actual data is increased. For example, a phenomenon, in which the neural network learning a cat while seeing a yellow cat cannot recognize cats, other than a yellow cat, as cats, is a sort of overfitting. Overfitting may act as a reason of increasing an error of a machine learning algorithm. In order to prevent overfitting, various optimizing methods may be used. In order to prevent overfitting, a method of increasing training data, a regularization method, a dropout method of inactivating a part of nodes of the network during the training process, a method using a bath normalization layer, and the like may be applied.

According to an exemplary embodiment of the present disclosure, the neural network model may be used during the semiconductor design process. For example, during a process of designing the semiconductor by using reinforcement learning, an agent of the reinforcement learning may be implemented as the neural network model.

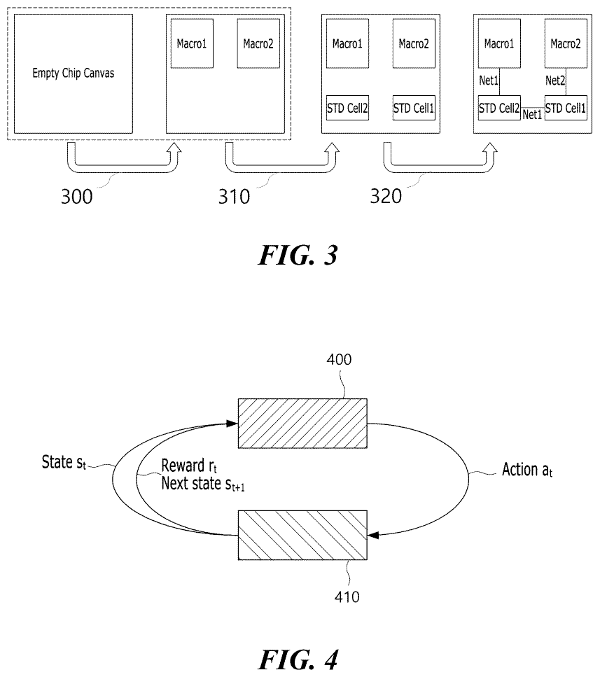

FIG. 3 is a conceptual view illustrating a basic semiconductor design process.

Prior to the description, the term canvas used in the present disclosure may be understood as a type of design area where cells are placed. In the present disclosure, the expression canvas is used for the convenience of description overall, but it may be understood as the design area in the same sense as the context mentioned above. In other words, even if it is expressed as the canvas, it may not be limited to the canvas, but also include other things that may correspond to the design area.

The design of the semiconductor requires Netlist information that defines a connection relationship between the cells. In the netlist information, the semiconductor cells are divided into relatively large macro cells and relatively small standard cells. The macro cell has no separate specification for a size, and is constituted by millions of transistors, which are usually larger than the standard cell. For example, the macro cell includes an SRAM or CPU core. The standard cell refers to a small unit of cell having a basic function, which is constituted by one or more transistors. The standard cell provides a storage function such as a simple logical operation (e.g., AND, OR, XOR) or a flip-flop, and also provide a more complicated function such as a 2-bit full adder or a multi-D input flip-flop. The standard cell has a specification for the size unlike the macro cell. In this case, since a standard for a size is not determined with respect to the macro cells, the processor 110 is downloaded with information related to the sizes of the macro cells from the network unit 150 or read the information related to the sizes of the macro cells from the memory 130 to acquire the information related to the sizes of the macro cells.

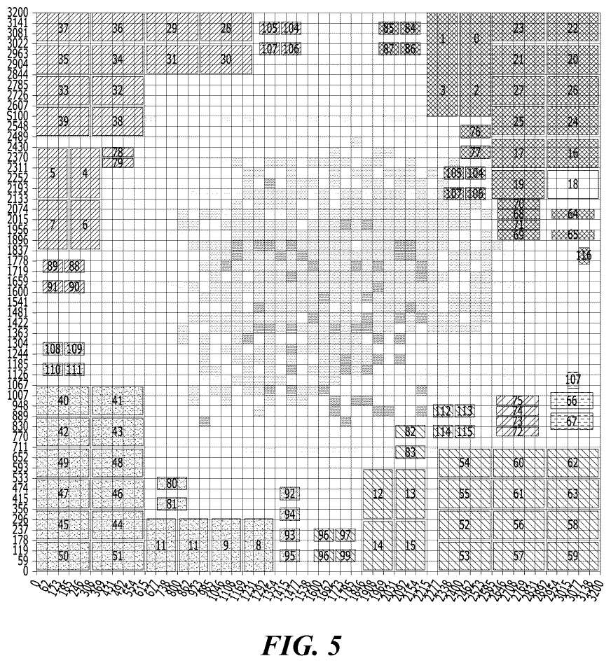

Referring to FIG. 3, a process for designing the semiconductor may be divided into three steps. First, a floorplan step 300 is performed in which a macro cell which is a relatively large cell is placed in an empty canvas. Next, a placement step 310 is performed in which the macro cell is placed in the canvas and a standard cell is placed in a remaining space. Last, a routing step 320 is performed in which the macro cell and the standard cell placed in the canvas are physically connected through a wire. Results in which the cells are placed in the canvas through the design process may be acquired by taking FIG. 5 as an example.

Whether a good design is made through the semiconductor design process may be evaluated through an evaluation item called PPA. The PPA is an abbreviation of power, performance, and area. According to the PPA, the semiconductor design aims to obtain low production cost with a small area, i.e., a high integrity while showing lower power consumption and high performance. In order to optimize the PPA according to the goal, a length of the wire connecting the semiconductor cells should be reduced. When the length of the wire connecting the cells is short, the reach of an electric signal may be accelerated, thermal energy generated in proportion to a length of the wire may be reduced, and power loss may be reduced. Moreover, obviously, as the overall use of wires is reduced, the integrity of cells increases, which may increase the number of cells that may be placed on a limited canvas. Therefore, in order to design the semiconductor well, an indicator related to the aforementioned PPA needs to be considered, and may be used as a reward evaluation for a case where the reinforcement learning model performs a specific operation.

According to the above-described perspective, for a good design (e.g., optimized PPA), it may be considered to simply place all cells close together. However, since routing resources, which represent resources that may allocate wires to each canvas, are limited, it is realistically impossible to simply place all cells close together. For example, if another wire already exists in a path along which the wire for connecting two cells passes, the wire for connecting the two cells may be placed bypassing the other wire. In this case, as the wire is bypassed and placed, the length of the wire becomes longer and the space occupied by the wire increases, which may affect the placement of the wire for connecting subsequent cells. In other words, because routing resources, which are resources that may physically allocate wires in the canvas, are limited, if cells are placed without considering routing resources, the PPA for the design result may deteriorate.

Therefore, for good design, it is important to consider the overall connectivity in the canvas, including macro cells and standard cells, from the floorplan step 300 of placing macro cells having a relatively large size and a lot of connectivities (i.e., in advance, it is important to consider routing). However, currently the floorplan step 300 is mainly performed manually by engineers. For example, in the floor plan step 300, macro cells are placed according to the engineer's intuition. At this time, engineers often place macro cells at the edges of the canvas, leaving the center space for standard cell placement. After the macro cell is placed, the engineer places the standard cell using the functions provided by existing rule-based tools. In other words, the current semiconductor design process is performed by largely relaying on the experience of engineers. In reality, this method is very difficult to place the cells with the connection relationships of tens to millions of cells in mind, so there is a problem that the speed of work and the quality of the results vary depending on the engineer's skill level.

In accordance with the aspects mentioned above, there is a trend in which engineer's tasks are being automated based on neural network models. However, when automating an engineer's task (i.e., semiconductor design), it is difficult to derive the optimal placement by considering all the connection relationships of numerous cells due to the excessive computation amount. In other words, considering the connection relationships between tens to millions of cells using the neural network model, there are many factors that the neural network model must consider when placing, so there is a problem in that it takes too much time to optimize the neural network model or perform predictions. As a solution to improve this problem, it is desirable to use a design method based on grouping of macro cells according to an exemplary embodiment of the present disclosure. However, the method according to an exemplary embodiment of the present disclosure is not limited to this purpose and can be used for various purposes.

On the other hand, when the chip die (e.g., canvas), which is defined as a continuous space, is defined as a discrete space, when macro cells of different sizes are placed, a so-called dead space may inevitably occur where other macro cells may not be placed. At this time, when designing the semiconductor using the grouped macros in the method according to an exemplary embodiment of the present disclosure, the placement is performed by considering the placement of the macro cells within the group in advance, so the risk of the dead space mentioned above may be reduced (in other words, the risk is reduced from the macro number unit to the group number unit). Further, in a situation in which all of the macro cells are placed in the canvas by using the grouped macro, even when another optimization method other than the method according to an exemplary embodiment of the present disclosure is used, the macro group unit may be considered instead of considering all respective macros in the related art, so the complexity of a computation which should be performed by the processor 110 may be significantly lowered. Further, in the placement of the macro in the related art, a direction of a pin (contact) included in the macro is very important, and since the direction of the macro may be fixed in the group by grouping macros having a strong connection relationship, the processor 110 may resolve a difficulty that the connectivity according to the direction of the pin should be considered every macro cells when designing the semiconductor.

FIG. 4 is a conceptual view for describing a reinforcement learning process of a neural network model according to an exemplary embodiment of the present disclosure.

The reinforcement learning model as a kind of neural network model may mean a model of determining a possible option as an action based on a state which an agent 400 acquires from a surrounding environment 410, and a series of processes may be referred to as one episode, and the reinforcement learning model may be gradually trained based on a reward which is a feedback calculated for an action selected every episode. That is, the reinforcement learning may be appreciated as learning through trial and error in that the reward is given for the determination (i.e., action). According to an exemplary embodiment of the present disclosure, the reinforcement learning model may perform reinforcement learning related to placement in units of the macro group. For example, the action of the reinforcement learning model may include an action of determining the placement position of the macro group to maximize the reward. Further, as an additional example, the action of the reinforcement learning model may include an action of jointly performing “sub-action of determining the placement position of the macro group” and “sub-action of determining a formation of the macro cells included in the macro group to be placed” in order to maximize the reward.

In this case, the reward may be calculated based on at least one of a connection (e.g., the length of the wire connecting the semiconductor cells) of the semiconductor cells placed in the canvas (design area), and a congestion of the semiconductor cells placed in the canvas. For example, the reward may be computed by a weighed sum of the connection and the congestion, and implemented in the form of a negative reward and a positive reward. According to an exemplary embodiment of the present disclosure, the reward may be calculated based on the macro group-unit placement. In an exemplary embodiment, the reward may be computed by a weighed sum of the connection (e.g., the length of the wire) and the congestion between the semiconductor cells computed by considering the placement position (macro_p) of the macro group to be placed. Specifically, the reward may be computed based on [Equation 1] below.

$${R}_{marcro \_ p} = ( - α * {W}_{marco \_ p} ) + ( - β * {C}_{macro \_ p} ) \qquad [ Equation 1 ]$$

Where R_{macro_p} may correspond to a reward related to the macro group-unit placement, and α and β may correspond to coefficients for adjusting the overall scale. Further, W_{marco_p} may correspond to a connection between semiconductor cells predicted in relation to the macro group-unit placement, and C_{macro_p} may correspond to a congestion between semiconductor cells predicted in relation to the macro group-unit placement.

Further, the reward may be determined based on a total length of wires to be included in the canvas, a congestion between the semiconductor cells to be included in the canvas, an integration of the semiconductor cells to be included in the canvas, and energy consumption due to the semiconductor cells to be included in the canvas, and the wire. For example, the reward may be computed by a weighed sum of the connection (e.g., the length of the wire), the congestion, the integration, and the energy consumption of between the semiconductor cells computed by considering the placement position (macro_p) of the macro group to be placed, and implemented in a form in which a negative reward and a positive reward are mixed. Specifically, the reward may be computed based on [Equation 2] below.

$${R}_{{marcro}_{p}} = ( - α * {W}_{{marco}_{p}} ) + ( - β * {C}_{{marco}_{p}} ) + ( + γ * {I}_{{marco}_{p}} + ( - δ * {E}_{marco \_ p} ) \qquad [ Equation 2 ]$$

Where R_{macro_p} may correspond to the reward related to the macro group-unit placement, and a to δ may correspond to coefficients for adjusting the overall scale. Further, W_{marco_p} may correspond to the connection between semiconductor cells predicted in relation to the macro group-unit placement, and C_{macro_p} may correspond to the congestion between semiconductor cells predicted in relation to the macro group-unit placement. Further, I_{marco_p} may correspond to the integration between semiconductor cells predicted in relation to the macro group-unit placement, and I_{macro_p} may correspond to the energy consumption between semiconductor cells predicted in relation to the macro group-unit placement.

For reference, the connection may be computed based on the length of the wire required to connect the semiconductor cells. Further, the congestion may be computed as a ratio of a second routing resource indicating a required resource for connecting the semiconductor cells placed in the canvas by the wire to a first routing resource indicating a supplied resource to which the wire may be allocated for each area of the canvas. Further, the integration may be exemplarily computed based on a density of semiconductor cells for an entire design area (e.g., canvas). Further, the energy consumption may be exemplarily computed based on energy consumption predicted in relation to operations of the semiconductor cells as expressed.

Meanwhile, the reward may also be computed by considering both “placement position (macro_p)” and “placement formation (macro_f)” of the macro group to be placed.

For example, the reward may be computed by a weighed sum of a connection (e.g., the length of the wire) and the congestion between the semiconductor cells computed by considering both the placement position (macro_p) and the placement formation (macro_f) of the macro group to be placed. Specifically, the reward may be computed based on [Equation 3] below.

$${R}_{marcro \_ p \& f} = ( - α * {W}_{marco \_ p \& f} ) + ( - β * {C}_{macro \_ p \& f} ) \qquad [ Equation 3 ]$$

Where R_{macro_p&f} may correspond to a reward related to “determination of the macro group-unit placement position and placement formation”, and a and R may correspond to coefficients for adjusting the overall scale. Further, W_{marco_p&f} may correspond to a connection between semiconductor cells predicted in relation to “determination of the macro group-unit placement position and placement formation”, and C_{macro_p&f} may correspond to a congestion between semiconductor cells predicted in relation to “determination of the macro group-unit placement position and placement formation.”

Further, the reward may be computed by a weighed sum of the connection (e.g., the length of the wire), the congestion, the integration, and the energy consumption of the semiconductor cells computed by considering the placement position (macro_p) and the placement formation (macro_f) of the macro group to be placed, and implemented in a form in which a negative reward and a positive reward are mixed. Specifically, the reward may be computed based on [Equation 4] below.

$${R}_{marco \_ p \& f} = ( - α * {W}_{marco \_ p \& f} ) + ( - β * {C}_{marco \_ p \& f} ) + ( + γ * {I}_{marco \_ p \& f} + ( - δ * {E}_{marco \_ p \& f} ) \qquad [ Equation 4 ]$$

Where R_{macro_p&f} may correspond to a reward related to “determination of the macro group-unit placement position and placement formation,” and a to F may correspond to coefficients for adjusting the overall scale. Further, W_{marco_p&f} may correspond to a connection between semiconductor cells predicted in relation to “determination of the macro group-unit placement position and placement formation,” and C_{macro_p&f} may correspond to a congestion of semiconductor cells predicted in relation to “determination of the macro group-unit placement position and placement formation.” Further, D_{marco_p&f} may correspond to an integration of semiconductor cells predicted in relation to “determination of the macro group-unit placement position and placement formation,” and E_{macro_p&f} may correspond to energy consumption predicted in relation to “determination of the macro group-unit placement position and placement formation.”

Meanwhile, the reward may be calculated by considering all cells to be placed in the design area (e.g., canvas), or may be calculated limited to macro cells among all cells.

Hereinafter, operations for designing the semiconductor based on grouping the macro cells according to an exemplary embodiment of the present disclosure will be described in more detail.

According to an exemplary embodiment of the present disclosure, the processor 110 may perform an operation of acquiring connection relationship information between placed cells. Here, the connection relationship information may include various information indicating a connection relationship between semiconductor cells. For example, the connection relationship information may include netlist information. Additionally, the netlist information may include information related to a hierarchical structure between semiconductor cells, information related to types of semiconductor cells, information related to sizes of semiconductor cells, etc.

According to an exemplary embodiment of the present disclosure, the processor 110 may generate two or more macro groups by grouping macro cells included in the connection relationship information. In this case, the processor 110 may generate the two or more macro groups based on layer information included in the connection relationship information.

For example, the processor 110 may generate a macro group based on the “layer information” included in the Netlist information. Specifically, the processor 110 may generate two or more macro groups in such a way that each macro group includes macro cells belonging to a same layer in the netlist.

Further, the processor 110 may generate the macro group by considering both the “layer information” and “cell type information” included in the Netlist information. For example, the processor 110 may generate two or more macro groups in such a way that each macro group includes macro cells belonging to a same layer and having the same cell type in the netlist. Meanwhile, the cell type information may be determined based on circuit characteristic information of each macro cell. Further, the cell type information may be identified based on a name of each macro cell.

Further, the processor 110 may generate the macro group by considering both the “layer information” and “specific size information” included in the Netlist information. For example, the processor 110 may generate two or more macro groups in such a way that each macro group includes macro cells belonging to a same layer and having the same size in the netlist. Meanwhile, the specific size information may mean specific size information of each macro cell. Each macro cell is classified as a macro cell because each macro cell has a larger size than standard cells, but since each macro cell may have the same or different specific size, the specific size information of each macro cell is considered as an additional criterion to group the macro cells.

Further, the processor 110 may also generate the macro group by considering all of the “layer information,” the “cell type information,” and the “specific size information” in addition to each of the “layer information,” the “cell type information,” and the “specific size information” included in the Netlist information. For example, the processor 110 may generate two or more macro groups in such a way that each macro group includes macro cells belonging to a same layer and having the same cell type and the same size in the netlist. In this case, since the processor 110 may jointly group and place macro cells having the same circuit characteristics and the same size while considering a hierarchical connection relationship, the processor 110 may more efficiently use a space of the design area (e.g., canvas), and perform placement while treating each macro group as a module having a specific function.

Further, according to an exemplary embodiment of the present disclosure, the processor 110 may perform an operation of placing two or more generated macro groups in the design area. That is, the processor 110 may perform an operation of placing the macro cells in the design area in units of the macro group. Further, the processor 110 may perform “an operation of determining the formation of each macro group” and “an operation of determining the placement position of each macro group” in relation to placement of each macro group. Meanwhile, as described above, the operations may be performed by the reinforcement learning model, and the reward for the action of the reinforcement learning model may also be determined in association with the macro group-unit placement (for example, the determination of the formation of each macro group and the determination of the placement position of each macro group).

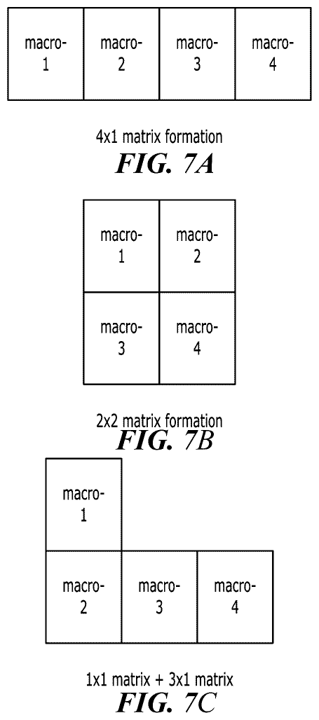

In an exemplary embodiment, the processor 110 may perform “an operation of selecting at least one of a plurality of matrix forms for each macro group” and “an operation of determining a form in which the macro cells included in the respective macro groups should be maintain together based on the matrix form selected for each macro group” in relation to “the operation of determining the formation of each macro group.” For example, (1) the processor 110 may select a 1×4 matrix form such as shown in FIG. 7A among the plurality of matrix forms for a first macro group, and make the first macro group maintain the 1×4 matrix form. Specifically, the processor 110 may place the first macro group at a 1-1^{st} position or a 1-2^{nd} position while maintaining the formation of the first macro group as the 1×4 matrix. Meanwhile, the placement formation of the first macro group may also be dynamically changed while mutually depending on the placement position of the first macro group. Specifically, the processor 110 may determine the position of the first macro group as a 1-3^{rd} position while determining the formation of the first macro group as the 1×4 matrix, or determine the position of the first macro group as a 1-4^{th} position while determining the formation of the first macro group as a 4×1 matrix. (2) Further, the processor 110 may select a 2×2 matrix form such as shown in FIG. 7B among the plurality of matrix forms for the second macro group, and make the second macro group maintain a 2×2 matrix form. Specifically, the processor 110 may place the second macro group at a 2-1^{st} position or a 2-2nd position while maintaining the formation of the second macro group as the 2×2 matrix. Meanwhile, the placement formation of the second macro group may also be dynamically changed while mutually depending on the placement position of the second macro group. Specifically, the processor 110 may determine the position of the second macro group as a 2-3^{rd} position while determining the formation of the second macro group as the 2×2 matrix, or determine the position of the second macro group as a 2-4^{th} position while determining the formation of the second macro group as a 1×4 matrix.

Additionally, the processor 110 may perform “an operation of selecting two or more matrix forms of the plurality of matrix forms for some macro groups” and “an operation of determining a form in which the macro cells included in the respective macro groups should be maintain together based on a form in which two or more matrix forms are combined” in relation to “the operation of determining the formation of each macro group.” (3) For example, the processor 110 may select the 1×1 matrix and the 1×3 matrix among the plurality of matrix forms for a third macro group, generate a “L” form in which the 1×1 matrix and the 1×3 matrix are successively combined with each other as shown in FIG. 7C, and make the third macro group maintain the combined “L” form. Specifically, the processor 110 may place the third macro group at a 3-1^{st} position or a 3-2^{nd} position while maintaining the formation of the third macro group as the combined “L” form. Meanwhile, the placement formation of the third macro group may also be dynamically changed while mutually depending on the placement position of the third macro group. Specifically, the processor 110 may determine the position of the third macro group as a 3-3^{rd} position while determining the formation of the third macro group as the “L” form in which the 1×1 matrix and the 1×3 matrix are successively combined, or determine the position of the third macro group as a 3-4^{th} position while determining the formation of the third macro group as a “¬” form in which the 1×1 matrix and the 1×3 matrix are successively combined.

Meanwhile, in the example of FIGS. 7A, 7B, 7C, the shape of each macro cell is depicted as being square, but is not limited to such a shape, and the matrix form may also be generated while each macro cell is implemented as a different shape such as a rectangle.

In an exemplary embodiment, the processor 110 may perform “an operation of determining a reference position in each macro group,” “an operation of determining the placement position of each macro group in the design area,” “an operation of placing each macro group to match the placement position and the reference position with each other,” etc., in relation to “the operation of determining the placement position of each macro group.”

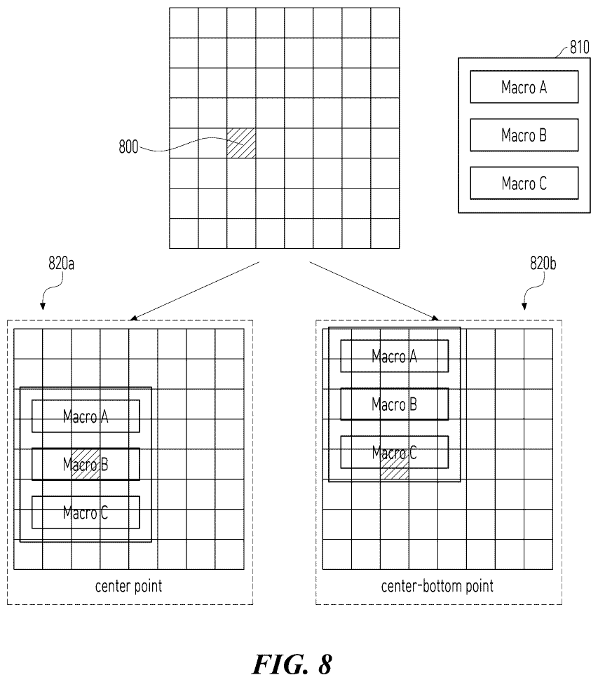

Here, the reference position in each macro group may be determined based on a bounding box of each macro group. For example, the processor 110 may generate a rectangular bounding box which ay encompass all of the macro cells of each macro group, and determine the reference position each macro group based on an entire shape of the generated bounding box, for each macro group. Specifically, as in a left example of FIG. 8, the processor 110 may determine a geometric center point of the bounding box of each macro group as the reference position of each macro group, and then place each macro group. Further, as in a right example of FIG. 8, the processor 110 may determine a center-bottom point of the bounding box of each macro group as the reference position of each macro group, and then place each macro group. Meanwhile, in addition to the examples, the processor 110 may determine a center-top point of the bounding box of each macro group, a center-leftmost point of the bounding box of each macro group, or a center-rightmost point of the bounding box of each macro group as the reference position of each macro group, and then place each macro group.

In addition, the placement position of each macro group within the design area means a position where each macro group should be placed within the design area. In an exemplary embodiment, the placement position of each macro group may mean a position in the design area which the reference position of each macro group should match when each macro group is placed. Further, when the design area is implemented as a canvas including a grid shaped space, the placement position of each macro group may correspond to one area in the grid-shaped space.

Further, the processor 110 may place each macro group so that the placement position and the reference position of each macro group match each other with respect to each macro group. For example, as in FIG. 8, the processor 110 may determine, with respect to an exemplary macro group 810 including macro cell A, macro cell B, and macro cell C, a center point of a bounding box of the exemplary macro group 810 as a reference position of the exemplary macro group 810, and then place the exemplary macro group (820a) while matching an area 800 in a grid-shaped space determined as a placement position of the exemplary macro group 810 with the center point. As an additional example, as in FIG. 8, the processor 110 may determine, with respect to the exemplary macro group 810 including macro cell A, macro cell B, and macro cell C, a center-bottom point of the bounding box of the exemplary macro group 810 as the reference position of the exemplary macro group 810, and then place the exemplary macro group (820b) while matching an area 800 in the grid-shaped space determined as the placement position of the exemplary macro group 810 with the center-bottom point.

Meanwhile, when the placement and the design for the macro cells are performed on a canvas including a grid-shaped discrete space, actual placement for the macro cells is performed on a die including a continuous space, so an error may occur. According to an exemplary embodiment of the present disclosure, the processor 110 may reduce the number of placements performed in the design process by performing placement in units of macro groups rather than in units of individual macro cells, thereby reducing the number of occurrences of design errors. In addition, the processor 110 may allow “an error which occurs due to an environmental difference in which the design is performed in a grid shaped discrete space, and elements are placed in continuous spaces” to occur in a macro group unit, and prevent the error from occurring in individual macro units, thereby further reducing design errors.

Additionally, according to an exemplary embodiment of the present disclosure, the processor 110 internally sets a margin area in each macro group to further reduce the design errors. Specifically, the processor 110 may set the margin area between at least two macro cells included in each macro group. For example, the processor 110 may set a first margin area between macro cell A and macro cell B, and set a second margin area between macro cell B and macro cell C, in the exemplary macro group 810 of FIG. 8. Through the margin area in each macro group, even when a space (for example, a space actually allocated to each macro group among in the continuous space on the actual placed die) in which each macro group is to be placed is different from (for example, narrower than) a space planned by design (for example, a space allocated to each macro group in the space of the grid-shaped canvas by design each macro group), a space may be secured in which the macro cells in each macro group maintains the placement formation determined by design, thereby further reducing the design errors.

Additionally, according to an exemplary embodiment of the present disclosure, the processor 110 may dynamically change the reference position in each macro group. Specifically, the processor 110 may dynamically change the reference position in each macro group by relying on a change in placement position of each macro group. For example, the processor 110 may (1) dynamically determine, when a placement position of any macro group is determined to be in the vicinity of an upper edge of the canvas, “a center-top point of a bounding box of the any macro group” as a reference position in the any macro group, (2) dynamically determine, when the placement position of the any macro group is determined to be in the vicinity of a lower edge of the canvas, “a center-bottom point of the bounding box of the any macro group” as the reference position in the any macro group, (3) dynamically determine, when the placement position of the any macro group is determined to be in the vicinity of a left edge of the canvas, “a center-leftmost point of the bounding box of the any macro group” as the reference position in the any macro group, and (4) dynamically determine, when the placement position of the any macro group is determined to be in the vicinity of a right edge of the canvas, “a center-rightmost point of the bounding box of the any macro group” as the reference position in the any macro group. Meanwhile, the processor 110 additionally uses the dynamic reference position to additionally implement an effect of being capable of more reliably preventing an event in which the any macro group is placed out of the design area, an effect of preventing a dead space which may be generated when the any macro group is placed in the vicinity of the edge of the design area, and an effect of being capable of further expanding a candidate placement area in which the any macro group may be placed compared to a case of using a fixed reference position.

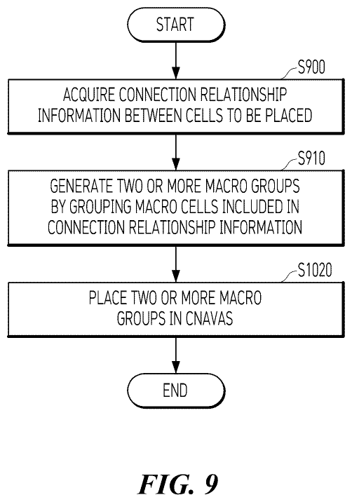

FIG. 9 is a flowchart generally illustrating “a method for designing a semiconductor” according to an exemplary embodiment of the present disclosure.

“A method for designing the semiconductor” according to an exemplary embodiment of the present disclosure to be described below may be performed by the computing device 100 described above. Therefore, although it will not be described in detail to prevent redundant description, the features described above with respect to the computing device 100 can naturally be applied by analogy to the “method of designing the semiconductor” according to an exemplary embodiment of the present disclosure.

In addition, the “method of designing the semiconductor” may be implemented in the form of a program that may be executed by a processor and implemented in a form which can be stored in a storage medium. Additionally, the method may be implemented in a form that can be distributed online.

Referring to FIG. 9, the “method for designing the semiconductor” according to an exemplary embodiment of the present disclosure may be performed by the computing device 100 described above, and the method may include a step S900 of acquiring connection relationship information between cells to be placed, a step S910 of generating two or more macro groups by grouping macro cells included in the connection relationship information, and step S920 of placing the two or more macro groups in a design area. Here, the two or more macro groups may be generated based on layer information included in the connection relationship information. Further, the method may include various additional steps in addition to the steps.

Step S900 above is a step of acquiring connection relationship information between cells to be placed.

Here, the connection relationship information may include various information indicating a connection relationship between semiconductor cells. For example, the connection relationship information may include netlist information. Additionally, the netlist information may include information related to a hierarchical structure between semiconductor cells, information related to types of semiconductor cells, information related to sizes of semiconductor cells, etc.

Step S910 above is a step of generating two or more macro groups by grouping macro cells included in the connection relationship information.

In an exemplary embodiment, in relation to step S910 above, each macro group may include macro cells belonging to the same layer in the netlist. Further, each macro group may also include macro cells belonging to the same layer, and having a same cell type or a same size in the netlist.

Step S920 above is a step of placing the two or more macro groups in a design area.

In an exemplary embodiment, step S920 above may include a step S920-1 of determining a formation of each macro group, and a step S920-2 of determining a placement position of each macro group.

Here, step S920-1 above may include a step S920-1-1 of selecting at least one of a plurality of matrix forms with respect to each macro group, and a step S920-1-2 of determining a form of the macro cells included in each macro group are to maintain together based on a selected matrix form with respect to each macro group.

Further, step S920-1-1 above may include selecting two or more matrix forms, and step S920-1-2 above may include determining the form which the macro cells included in each macro group are to maintain together based on a form in which the two or more matrix forms are combined.

Next, step S920-2 above may include step S920-2-1 of determining a reference position in each macro group, step S920-2-2 of determining the placement position of each macro group in the design area, and step S920-2-3 of placing each macro group to match the placement position and the reference position each other.

In this regard, the reference position of the macro group may include a center point of a bounding box of a selected macro group, a center-bottom point of the bounding box of the selected macro group, a center-top point of the bounding box of the selected macro group, a center-leftmost point of the bounding box of the selected macro group, or a center-rightmost point of the bounding box of the selected macro group.

Further, the design area may include a canvas, the canvas may include a grid-shaped space, and the placement position may correspond to one area in the grid-shaped space. Further, the canvas in which the two or more macro groups are placed for design may include a grid-shaped discrete space, and a die in which the two or more macro groups are to be placed may include a continuous space. Further, each macro group may also include a margin area formed between at least two macro cells.

Meanwhile, step S920 above may also include performing reinforcement learning based on a reward related to macro group-unit placement. Here, an action of the reinforcement learning may include determining formations of macro cells included in a macro group to be placed, and determining a placement position of the macro group to be placed. Further, the reward may be calculated based on at least one of a connection or a congestion between cells computed by considering both the formation and the placement position of the macro group to be placed. Additionally, the reward related the macro group-unit placement may be calculated based on at least one of a connection between cells to be included in the design area, a congestion between the cells to be included in the design area, an integration of the cells to be included in the design area, or energy consumption due to the wires and cells to be included in the design area.

In the meantime, according to an embodiment of the present disclosure, a computer readable medium storing a data structure is disclosed.

The data structure may refer to organization, management, and storage of data that enable efficient access and modification of data. The data structure may refer to organization of data for solving a specific problem (for example, data search, data storage, and data modification in the shortest time). The data structure may also be defined with a physical or logical relationship between the data elements designed to support a specific data processing function. A logical relationship between data elements may include a connection relationship between user defined data elements. A physical relationship between data elements may include an actual relationship between the data elements physically stored in a computer readable storage medium (for example, a permanent storage device). In particular, the data structure may include a set of data, a relationship between data, and a function or a command applicable to data. Through the effectively designed data structure, the computing device may perform a calculation while minimally using resources of the computing device. In particular, the computing device may improve efficiency of calculation, reading, insertion, deletion, comparison, exchange, and search through the effectively designed data structure.

The data structure may be divided into a linear data structure and a non-linear data structure according to the form of the data structure. The linear data structure may be the structure in which only one data is connected after one data. The linear data structure may include a list, a stack, a queue, and a deque. The list may mean a series of dataset in which order exists internally. The list may include a linked list. The linked list may have a data structure in which data is connected in a method in which each data has a pointer and is linked in a single line. In the linked list, the pointer may include information about the connection with the next or previous data. The linked list may be expressed as a single linked list, a double linked list, and a circular linked list according to the form. The stack may have a data listing structure with limited access to data. The stack may have a linear data structure that may process (for example, insert or delete) data only at one end of the data structure. The data stored in the stack may have a data structure (Last In First Out, LIFO) in which the later the data enters, the sooner the data comes out. The queue is a data listing structure with limited access to data, and may have a data structure (First In First Out, FIFO) in which the later the data is stored, the later the data comes out, unlike the stack. The deque may have a data structure that may process data at both ends of the data structure.

The non-linear data structure may be the structure in which the plurality of data is connected after one data. The non-linear data structure may include a graph data structure. The graph data structure may be defined with a vertex and an edge, and the edge may include a line connecting two different vertexes. The graph data structure may include a tree data structure. The tree data structure may be the data structure in which a path connecting two different vertexes among the plurality of vertexes included in the tree is one. That is, the tree data structure may be the data structure in which a loop is not formed in the graph data structure.

Throughout the present specification, a calculation model, a nerve network, the network function, and the neural network may be used with the same meaning. Hereinafter, the terms of the calculation model, the nerve network, the network function, and the neural network are unified and described with a neural network. The data structure may include a neural network. Further, the data structure including the neural network may be stored in a computer readable medium. The data structure including the neural network may also include preprocessed data for processing by the neural network, data input to the neural network, a weight of the neural network, a hyper-parameter of the neural network, data obtained from the neural network, an active function associated with each node or layer of the neural network, and a loss function for training of the neural network. The data structure including the neural network may include predetermined configuration elements among the disclosed configurations. That is, the data structure including the neural network may include the entirety or a predetermined combination of pre-processed data for processing by neural network, data input to the neural network, a weight of the neural network, a hyper parameter of the neural network, data obtained from the neural network, an active function associated with each node or layer of the neural network, and a loss function for training the neural network. In addition to the foregoing configurations, the data structure including the neural network may include predetermined other information determining a characteristic of the neural network. Further, the data structure may include all type of data used or generated in a computation process of the neural network, and is not limited to the foregoing matter. The computer readable medium may include a computer readable recording medium and/or a computer readable transmission medium. The neural network may be formed of a set of interconnected calculation units which are generally referred to as “nodes.” The “nodes” may also be called “neurons.” The neural network consists of one or more nodes.

The data structure may include data input to the neural network. The data structure including the data input to the neural network may be stored in the computer readable medium. The data input to the neural network may include training data input in the training process of the neural network and/or input data input to the training completed neural network. The data input to the neural network may include data that has undergone pre-processing and/or data to be pre-processed. The pre-processing may include a data processing process for inputting data to the neural network. Accordingly, the data structure may include data to be pre-processed and data generated by the pre-processing. The foregoing data structure is merely an example, and the present disclosure is not limited thereto.

The data structure may include a weight of the neural network (in the present specification, weights and parameters may be used with the same meaning), Further, the data structure including the weight of the neural network may be stored in the computer readable medium. The neural network may include a plurality of weights. The weight is variable, and in order for the neural network to perform a desired function, the weight may be varied by a user or an algorithm. For example, when one or more input nodes are connected to one output node by links, respectively, the output node may determine a data value output from the output node based on values input to the input nodes connected to the output node and the weight set in the link corresponding to each of the input nodes. The foregoing data structure is merely an example, and the present disclosure is not limited thereto.

For a non-limited example, the weight may include a weight varied in the neural network training process and/or the weight when the training of the neural network is completed. The weight varied in the neural network training process may include a weight at a time at which a training cycle starts and/or a weight varied during a training cycle. The weight when the training of the neural network is completed may include a weight of the neural network completing the training cycle. Accordingly, the data structure including the weight of the neural network may include the data structure including the weight varied in the neural network training process and/or the weight when the training of the neural network is completed. Accordingly, it is assumed that the weight and/or a combination of the respective weights are included in the data structure including the weight of the neural network. The foregoing data structure is merely an example, and the present disclosure is not limited thereto.

The data structure including the weight of the neural network may be stored in the computer readable storage medium (for example, a memory and a hard disk) after undergoing a serialization process. The serialization may be the process of storing the data structure in the same or different computing devices and converting the data structure into a form that may be reconstructed and used later. The computing device may serialize the data structure and transceive the data through a network. The serialized data structure including the weight of the neural network may be reconstructed in the same or different computing devices through deserialization. The data structure including the weight of the neural network is not limited to the serialization. Further, the data structure including the weight of the neural network may include a data structure (for example, in the non-linear data structure, B-Tree, Trie, m-way search tree, AVL tree, and Red-Black Tree) for improving efficiency of the calculation while minimally using the resources of the computing device. The foregoing matter is merely an example, and the present disclosure is not limited thereto.

The data structure may include a hyper-parameter of the neural network. The data structure including the hyper-parameter of the neural network may be stored in the computer readable medium. The hyper-parameter may be a variable varied by a user. The hyper-parameter may include, for example, a learning rate, a cost function, the number of times of repetition of the training cycle, weight initialization (for example, setting of a range of a weight value to be weight-initialized), and the number of hidden units (for example, the number of hidden layers and the number of nodes of the hidden layer). The foregoing data structure is merely an example, and the present disclosure is not limited thereto.

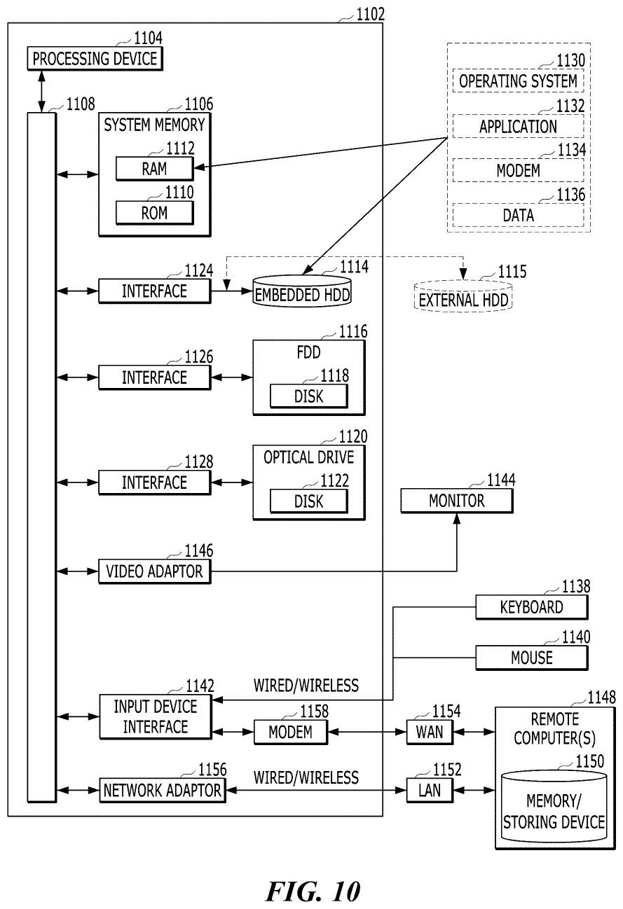

FIG. 10 is a simple and general schematic diagram illustrating an example of a computing environment in which the embodiments of the present disclosure are implementable.

The present disclosure has been described as being generally implementable by the computing device, but those skilled in the art will appreciate well that the present disclosure is combined with computer executable commands and/or other program modules executable in one or more computers and/or be implemented by a combination of hardware and software.

In general, a program module includes a routine, a program, a component, a data structure, and the like performing a specific task or implementing a specific abstract data form. Further, those skilled in the art will well appreciate that the method of the present disclosure may be carried out by a personal computer, a hand-held computing device, a microprocessor-based or programmable home appliance (each of which may be connected with one or more relevant devices and be operated), and other computer system configurations, as well as a single-processor or multiprocessor computer system, a mini computer, and a main frame computer.

The embodiments of the present disclosure may be carried out in a distribution computing environment, in which certain tasks are performed by remote processing devices connected through a communication network. In the distribution computing environment, a program module may be located in both a local memory storage device and a remote memory storage device.

The computer generally includes various computer readable media. The computer accessible medium may be any type of computer readable medium, and the computer readable medium includes volatile and non-volatile media, transitory and non-transitory media, and portable and non-portable media. As a non-limited example, the computer readable medium may include a computer readable storage medium and a computer readable transport medium. The computer readable storage medium includes volatile and non-volatile media, transitory and non-transitory media, and portable and non-portable media constructed by a predetermined method or technology, which stores information, such as a computer readable command, a data structure, a program module, or other data. The computer readable storage medium includes a RAM, a Read Only Memory (ROM), an Electrically Erasable and Programmable ROM (EEPROM), a flash memory, or other memory technologies, a Compact Disc (CD)-ROM, a Digital Video Disk (DVD), or other optical disk storage devices, a magnetic cassette, a magnetic tape, a magnetic disk storage device, or other magnetic storage device, or other predetermined media, which are accessible by a computer and are used for storing desired information, but is not limited thereto.

The computer readable transport medium generally implements a computer readable command, a data structure, a program module, or other data in a modulated data signal, such as a carrier wave or other transport mechanisms, and includes all of the information transport media. The modulated data signal means a signal, of which one or more of the characteristics are set or changed so as to encode information within the signal. As a non-limited example, the computer readable transport medium includes a wired medium, such as a wired network or a direct-wired connection, and a wireless medium, such as sound, Radio Frequency (RF), infrared rays, and other wireless media. A combination of the predetermined media among the foregoing media is also included in a range of the computer readable transport medium.

An illustrative environment 1100 including a computer 1102 and implementing several aspects of the present disclosure is illustrated, and the computer 1102 includes a processing device 1104, a system memory 1106, and a system bus 1108. The system bus 1108 connects system components including the system memory 1106 (not limited) to the processing device 1104. The processing device 1104 may be a predetermined processor among various commonly used processors. A dual processor and other multi-processor architectures may also be used as the processing device 1104.

The system bus 1108 may be a predetermined one among several types of bus structure, which may be additionally connectable to a local bus using a predetermined one among a memory bus, a peripheral device bus, and various common bus architectures. The system memory 1106 includes a ROM 1110, and a RAM 1112. A basic input/output system (BIOS) is stored in a non-volatile memory 1110, such as a ROM, an EPROM, and an EEPROM, and the BIOS includes a basic routing helping a transport of information among the constituent elements within the computer 1102 at a time, such as starting. The RAM 1112 may also include a high-rate RAM, such as a static RAM, for caching data.

The computer 1102 also includes an embedded hard disk drive (HDD) 1114 (for example, enhanced integrated drive electronics (EIDE) and serial advanced technology attachment (SATA))—the embedded HDD 1114 being configured for exterior mounted usage within a proper chassis (not illustrated)—a magnetic floppy disk drive (FDD) 1116 (for example, which is for reading data from a portable diskette 1118 or recording data in the portable diskette 1118), and an optical disk drive 1120 (for example, which is for reading a CD-ROM disk 1122, or reading data from other high-capacity optical media, such as a DVD, or recording data in the high-capacity optical media). A hard disk drive 1114, a magnetic disk drive 1116, and an optical disk drive 1120 may be connected to a system bus 1108 by a hard disk drive interface 1124, a magnetic disk drive interface 1126, and an optical drive interface 1128, respectively. An interface 1124 for implementing an outer mounted drive includes, for example, at least one of or both a universal serial bus (USB) and the Institute of Electrical and Electronics Engineers (IEEE) 1394 interface technology.

The drives and the computer readable media associated with the drives provide non-volatile storage of data, data structures, computer executable commands, and the like. In the case of the computer 1102, the drive and the medium correspond to the storage of random data in an appropriate digital form. In the description of the computer readable media, the HDD, the portable magnetic disk, and the portable optical media, such as a CD, or a DVD, are mentioned, but those skilled in the art will well appreciate that other types of computer readable media, such as a zip drive, a magnetic cassette, a flash memory card, and a cartridge, may also be used in the illustrative operation environment, and the predetermined medium may include computer executable commands for performing the methods of the present disclosure.

A plurality of program modules including an operation system 1130, one or more application programs 1132, other program modules 1134, and program data 1136 may be stored in the drive and the RAM 1112. An entirety or a part of the operation system, the application, the module, and/or data may also be cached in the RAM 1112. It will be well appreciated that the present disclosure may be implemented by several commercially usable operation systems or a combination of operation systems.

A user may input a command and information to the computer 1102 through one or more wired/wireless input devices, for example, a keyboard 1138 and a pointing device, such as a mouse 1140. Other input devices (not illustrated) may be a microphone, an IR remote controller, a joystick, a game pad, a stylus pen, a touch screen, and the like. The foregoing and other input devices are frequently connected to the processing device 1104 through an input device interface 1142 connected to the system bus 1108, but may be connected by other interfaces, such as a parallel port, an IEEE 1394 serial port, a game port, a USB port, an IR interface, and other interfaces.

A monitor 1144 or other types of display devices are also connected to the system bus 1108 through an interface, such as a video adaptor 1146. In addition to the monitor 1144, the computer generally includes other peripheral output devices (not illustrated), such as a speaker and a printer.

The computer 1102 may be operated in a networked environment by using a logical connection to one or more remote computers, such as remote computer(s) 1148, through wired and/or wireless communication. The remote computer(s) 1148 may be a work station, a computing device computer, a router, a personal computer, a portable computer, a microprocessor-based entertainment device, a peer device, and other general network nodes, and generally includes some or an entirety of the constituent elements described for the computer 1102, but only a memory storage device 1150 is illustrated for simplicity. The illustrated logical connection includes a wired/wireless connection to a local area network (LAN) 1152 and/or a larger network, for example, a wide area network (WAN) 1154. The LAN and WAN networking environments are general in an office and a company, and make an enterprise-wide computer network, such as an Intranet, easy, and all of the LAN and WAN networking environments may be connected to a worldwide computer network, for example, the Internet.

When the computer 1102 is used in the LAN networking environment, the computer 1102 is connected to the local network 1152 through a wired and/or wireless communication network interface or an adaptor 1156. The adaptor 1156 may make wired or wireless communication to the LAN 1152 easy, and the LAN 1152 also includes a wireless access point installed therein for the communication with the wireless adaptor 1156. When the computer 1102 is used in the WAN networking environment, the computer 1102 may include a modem 1158, is connected to a communication computing device on a WAN 1154, or includes other means setting communication through the WAN 1154 via the Internet. The modem 1158, which may be an embedded or outer-mounted and wired or wireless device, is connected to the system bus 1108 through a serial port interface 1142. In the networked environment, the program modules described for the computer 1102 or some of the program modules may be stored in a remote memory/storage device 1150. The illustrated network connection is illustrative, and those skilled in the art will appreciate well that other means setting a communication link between the computers may be used.

The computer 1102 performs an operation of communicating with a predetermined wireless device or entity, for example, a printer, a scanner, a desktop and/or portable computer, a portable data assistant (PDA), a communication satellite, predetermined equipment or place related to a wirelessly detectable tag, and a telephone, which is disposed by wireless communication and is operated. The operation includes a wireless fidelity (Wi-Fi) and Bluetooth wireless technology at least. Accordingly, the communication may have a pre-defined structure, such as a network in the related art, or may be simply ad hoc communication between at least two devices.

The Wi-Fi enables a connection to the Internet and the like even without a wire. The Wi-Fi is a wireless technology, such as a cellular phone, which enables the device, for example, the computer, to transmit and receive data indoors and outdoors, that is, in any place within a communication range of a base station. A Wi-Fi network uses a wireless technology, which is called IEEE 802.11 (a, b, g, etc.) for providing a safe, reliable, and high-rate wireless connection. The Wi-Fi may be used for connecting the computer to the computer, the Internet, and the wired network (IEEE 802.3 or Ethernet is used). The Wi-Fi network may be operated at, for example, a data rate of 11 Mbps (802.11a) or 54 Mbps (802.11b) in an unauthorized 2.4 and 5 GHz wireless band, or may be operated in a product including both bands (dual bands).

Those skilled in the art may appreciate that information and signals may be expressed by using predetermined various different technologies and techniques. For example, data, indications, commands, information, signals, bits, symbols, and chips referable in the foregoing description may be expressed with voltages, currents, electromagnetic waves, magnetic fields or particles, optical fields or particles, or a predetermined combination thereof.

Those skilled in the art will appreciate that the various illustrative logical blocks, modules, processors, means, circuits, and algorithm operations described in relationship to the embodiments disclosed herein may be implemented by electronic hardware (for convenience, called “software” herein), various forms of program or design code, or a combination thereof. In order to clearly describe compatibility of the hardware and the software, various illustrative components, blocks, modules, circuits, and operations are generally illustrated above in relation to the functions of the hardware and the software. Whether the function is implemented as hardware or software depends on design limits given to a specific application or an entire system. Those skilled in the art may perform the function described by various schemes for each specific application, but it shall not be construed that the determinations of the performance depart from the scope of the present disclosure.

Various embodiments presented herein may be implemented by a method, a device, or a manufactured article using a standard programming and/or engineering technology. A term “manufactured article” includes a computer program, a carrier, or a medium accessible from a predetermined computer-readable storage device. For example, the computer-readable storage medium includes a magnetic storage device (for example, a hard disk, a floppy disk, and a magnetic strip), an optical disk (for example, a CD and a DVD), a smart card, and a flash memory device (for example, an EEPROM, a card, a stick, and a key drive), but is not limited thereto. Further, various storage media presented herein include one or more devices and/or other machine-readable media for storing information.

It shall be understood that a specific order or a hierarchical structure of the operations included in the presented processes is an example of illustrative accesses. It shall be understood that a specific order or a hierarchical structure of the operations included in the processes may be rearranged within the scope of the present disclosure based on design priorities. The accompanying method claims provide various operations of elements in a sample order, but it does not mean that the claims are limited to the presented specific order or hierarchical structure.

The description of the presented embodiments is provided so as for those skilled in the art to use or carry out the present disclosure. Various modifications of the embodiments may be apparent to those skilled in the art, and general principles defined herein may be applied to other embodiments without departing from the scope of the present disclosure. Accordingly, the present disclosure is not limited to the embodiments suggested herein, and shall be interpreted within the broadest meaning range consistent to the principles and new characteristics presented herein.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for designing a semiconductor performed by a computing device, the method comprising:
acquiring connection relationship information between cells to be placed;
generating two or more macro groups by grouping macro cells included in the connection relationship information; and
placing the two or more macro groups in a design area,
wherein the two or more macro groups are generated based on layer information included in the connection relationship information, and
wherein the placing of the two or more macro groups in the design area includes:
outputting an action by a reinforcement learning agent including a sub-action of determining a placement position of a macro group to be placed and a sub-action of determining a formation of the macro group to be placed, based on a reward related to a macro group-unit placement, and
wherein the reward related to the macro group-unit placement is calculated based on at least one of a connection or a congestion between cells computed by considering the placement position and the formation of the macro group to be placed.

2. The method of claim 1, wherein the placing of the two or more macro groups in the design area includes:
determining a formation of each macro group; and
determining a placement position of each macro group.

3. The method of claim 2, wherein the determining of the placement position of each macro group includes:
determining a reference position in each macro group;
determining a placement position of each macro group in the design area; and
placing each macro group to match the placement position and the reference position each other.

4. The method of claim 3, wherein the reference position of the macro group includes:
a center point of a bounding box of a selected macro group;
a center-bottom point of a bounding box of a selected macro group;
a center-top point of a bounding box of a selected macro group;
a center-leftmost point of a bounding box of a selected macro group; or
a center-rightmost point of a bounding box of a selected macro group.

5. The method of claim 3, wherein the design area includes a canvas:
the canvas includes a grid-shaped space; and
the placement position corresponds to one area in the grid-shaped space.

6. The method of claim 5, wherein
the canvas in which the two or more macro groups are placed for design includes a grid-shaped discrete space; and
a die in which the two or more macro groups are to be placed includes a continuous space.

7. The method of claim 5, wherein each macro group includes a margin area formed between at least two macro cells.

8. The method of claim 1, wherein
the connection relationship information includes a netlist; and
each macro group includes macro cells belonging to a same layer in the netlist.

9. The method of claim 8, wherein each macro group includes macro cells belonging to the same layer in the netlist, and having a same cell type or a same size.

10. The method of claim 2, wherein the determining of the formation of each macro group includes:
selecting at least one of a plurality of matrix forms with respect to each macro group; and
determining a form of macro cells included in each macro group are to maintain together based on a selected matrix form with respect to each macro group.

11. The method of claim 10, wherein the selecting of at least one of the plurality of matrix forms with respect to each macro group includes:
selecting two or more matrix forms; and
the determining of the form of macro cells included in each macro group are to maintain together based on the matrix form selected with respect to each macro group includes:
determining the form of macro cells included in each macro group are to maintain together based on a form in which the two or more matrix forms are combined.

12. (canceled)

13. (canceled)

14. (canceled)

15. The method of claim 1, wherein the reward related the macro group-unit placement is calculated based on at least one of:
a connection between cells to be included in the design area;
a congestion between cells to be included in the design area;
an integration of cells to be included in the design area; or
energy consumption due to wires and cells to be included in the design area.

16. A computing device for designing a semiconductor, the device comprising:
at least one processor; and
a memory,
wherein the at least one processor is configured to:
acquire connection relationship information between cells to be placed;
generate two or more macro groups by grouping macro cells included in the connection relationship information; and
place the two or more macro groups in a design area; and
the two or more macro groups are generated based on layer information included in the connection relationship information; and
wherein the placing of the two or more macro groups in the design area includes:
outputting an action by a reinforcement learning agent including a sub-action of determining a placement position of a macro group to be placed and a sub-action of determining a formation of the macro group to be placed, based on a reward related to a macro group-unit placement, and
wherein the reward related to the macro group-unit placement is calculated based on at least one of a connection or a congestion between cells computed by considering the placement position and the formation of the macro group to be placed.

17. The device of claim 16, wherein the at least one processor is additionally configured to:
place the two or more macro groups in a design area;
determine a formation of each macro group; and
determine a placement position of each macro group.

18. The device of claim 17, wherein the at least one processor is additionally configured to:
determine a reference position in each macro group;
determine a placement position of each macro group in the design area; and
placing each macro group to match the placement position and the reference position each other.

19. The device of claim 18, wherein the reference position of the macro group includes:
a center point of a bounding box of a selected macro group; or
a center-bottom point of a bounding box of a selected macro group.

20. The device of claim 17, wherein
the connection relationship information includes a netlist; and
each macro group includes macro cells belonging to a same layer in the netlist.

21. The device of claim 20, wherein each macro group includes macro cells belonging to the same layer in the netlist, and having a same cell type or a same size.

22. The device of claim 16, wherein the at least one processor is additionally configured to:
determine the formation of each macro group;
select at least one of a plurality of matrix forms with respect to each macro group; and
determine a form of macro cells included in each macro group are to maintain together based on a selected matrix form with respect to each macro group.

23. The device of claim 22, wherein the at least one processor is additionally configured to:
select two or more matrix forms in relation to selecting at least one of the plurality of matrix forms; and
determine the form of macro cells included in each macro group are to maintain together based on a form in which the two or more matrix forms are combined, in relation to determine the form of macro cells included in each macro group are to maintain together.

24. A computer program stored in a non-transitory computer-readable storage medium, wherein when the computer program performs operations for designing a semiconductor when executed by at least one processor included in a computing device, and the operations comprising:
an operation of acquiring connection relationship information between cells to be placed;
an operation of generating two or more macro groups by grouping macro cells included in the connection relationship information; and
an operation of placing the two or more macro groups in a design area,
wherein the two or more macro groups are generated based on layer information included in the connection relationship information, and
wherein the operation of placing of the two or more macro groups in the design area includes:
an operation of outputting an action by a reinforcement learning agent including a sub-action of determining a placement position of a macro group to be placed and a sub-action of determining a formation of the macro group to be placed, based on a reward related to a macro group-unit placement, and
wherein the reward related to the macro group-unit placement is calculated based on at least one of a connection or a congestion between cells computed by considering the placement position and the formation of the macro group to be placed.

25. (canceled)

26. (canceled)

27. (canceled)

28. The computer program of claim 24, wherein the reward related the macro group-unit placement is calculated based on at least one of:
a connection between cells to be included in the design area;
a congestion between cells to be included in the design area;
an integration of cells to be included in the design area; or
energy consumption due to wires and cells to be included in the design area.
